(19) United States
(12) Patent Application Publication
(10) Pub. No.: US 2021/0143061 A1
(43) Pub. Date: May 13, 2021

(54) HYBRID METALLIZATION AND DIELECTRIC INTERCONNECTS IN TOP VIA CONFIGURATION

(71) Applicant: International Business Machines Corporation, Armonk, NY (US)

(72) Inventors: Hari Prasad AMANAPU, Guilderland, NY (US); Cornelius Brown PEETHALA, Slingerlands, NY (US); Raghuveer PATLOLLA, Guilderland, NY (US); Chih-Chao YANG, Glenmont, NY (US)

(21) Appl. No.: 16/676,573

(22) Filed: Nov. 7, 2019

(51) Int. Cl. H01L 21/768; H01L 23/522

(52) U.S. Cl. CPC H01L 21/76885; H01L 21/76883; H01L 23/5226

(57) ABSTRACT

A method for fabricating top-via interconnect structures includes forming a first dielectric layer on a substrate and an insulating layer on the first dielectric layer. At least one trench is formed that extends through the insulating layer and the first dielectric layer is also formed. An interconnect material is deposited and fills the at least one trench. The interconnect material is patterned into an interconnect structure having a top-via configuration. The insulating layer is removed after the interconnect material has been patterned. A second dielectric layer is formed on the first dielectric layer and the patterned interconnect structure.

### BACKGROUND OF THE INVENTION

The present invention generally relates to the field of semiconductors, and more particularly relates to fabricating interconnect structures.

Integrated circuit processing can be generally divided into front end of the line (FEOL), middle of the line (MOL) and back end of the line (BEOL) processes. FEOL and MOL processing generally forms many layers of logical and functional devices. For example, the typical FEOL processes include wafer preparation, isolation, well formation, gate patterning, spacer, extension and source/drain implantation, silicide formation, etc. The MOL is mainly gate contact formation. Layers of interconnections may be formed above these logical and functional layers during the BEOL processing to complete the integrated circuit structure. The BEOL interconnect structure typically comprises multiple levels of metal lines and inter-level metallic vias that connect various integrated circuit component and devices fabricated as part of the FEOL layer.

### SUMMARY OF THE INVENTION

In one embodiment, a method for forming one or more interconnect structures comprises forming a first dielectric layer on a substrate. An insulating layer is formed on the first dielectric layer. At least one trench is formed that extends through the insulating layer and the first dielectric layer. An interconnect material is deposited and fills the at least one trench. The interconnect material is patterned into an interconnect structure comprising a top-via configuration. The insulating layer is removed after the interconnect material has been patterned. A second dielectric layer is formed on the first dielectric layer and the patterned interconnect structure.

In another embodiment, an additional method for forming one or more interconnect structures comprises forming a dielectric layer on a substrate. An insulating layer is formed on the dielectric layer. At least one trench is formed that extends through the insulating layer and the dielectric layer. A first interconnect material is deposited and fills the at least one trench. The first interconnect material is etched down into the at least one trench to form a wire layer of an interconnect structure. A second interconnect structure is deposited into the at least one trench in contact with the metal wire. The second interconnect material is patterned to form a via pillar of the interconnect structure.

In further embodiment, a semiconductor structure comprises a first dielectric layer disposed over a substrate. A second dielectric layer is disposed over and in contact with the first dielectric layer. The first dielectric layer comprises a different dielectric material than the second dielectric layer. At least one interconnect is disposed within the first dielectric layer and the second dielectric layer. The at least one interconnect comprises a top-via configuration.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention, in which:

FIG. 1 is a cross-sectional view of a semiconductor structure after a first dielectric layer has been formed on a substrate comprising front-end-of-line and middle-of-line layers according to one embodiment of the present invention;

FIG. 2 is a cross-sectional view of the semiconductor structure after an insulating layer and patterning stack have been formed according to one embodiment of the present invention;

FIG. 3 is a cross-sectional view of the semiconductor structure after the insulating layer and first dielectric layer have been patterned to form interconnect trenches according to one embodiment of the present invention;

FIG. 4 is a cross-sectional view of the semiconductor structure after an interconnect material has been deposited within the interconnect trenches according to one embodiment of the present invention;

FIG. 5 is a cross-sectional view of the semiconductor structure after the interconnect material has been etched to form interconnect structures and a patterning stack has been formed according to one embodiment of the present invention;

FIG. 6 is a cross-sectional view of the semiconductor structure after the interconnect structures have been patterned into a top-via configuration each having a metal/metallic wire layer and a metal/metallic via pillar according to one embodiment of the present invention;

FIG. 7 is a cross-sectional view of the semiconductor structure after remaining portions of the insulating layer have been removed according to one embodiment of the present invention;

FIG. 8 is a cross-sectional view of the semiconductor structure after a second dielectric layer has been formed over the structure according to one embodiment of the present invention;

FIG. 9 is a cross-sectional view of a semiconductor structure after the processing of FIG. 4 has been completed and the interconnect material has been etched down to the insulating layer according to another embodiment of the present invention;

FIG. 10 is a cross-sectional view of the semiconductor structure after the interconnect material has been patterned to form a metal/metallic wire layers for interconnect structures according to another embodiment of the present invention;

FIG. 11 is a cross-sectional view of the semiconductor structure after an additional interconnect material has been formed over the metal/metallic wire layers according to another embodiment of the present invention;

FIG. 12 is a cross-sectional view of the semiconductor structure after excess additional interconnect material has been removed and a patterning stack has been formed thereon according to another embodiment of the present invention;

FIG. 13 is a cross-sectional view of the semiconductor structure after the additional interconnect material has been patterned to form metal/metallic via pillars in contact with a portion of the metal/metallic wire layers for the interconnect structures according to another embodiment of the present invention;

FIG. 14 is a cross-sectional view of the semiconductor structure after remaining portions of the insulating layer have been removed according to another embodiment of the present invention;

FIG. 15 is a cross-sectional view of the semiconductor structure after a second dielectric layer has been formed over the structure according to another embodiment of the present invention;

FIG. 16 is an operational flow diagram illustrating one example of a process for forming interconnect structures having a top-via configuration according to one embodiment of the present invention; and

FIG. 17 is an operational flow diagram illustrating another example of a process for forming interconnect structures having a top-via configuration according to another embodiment of the present invention.

### DETAILED DESCRIPTION

It is to be understood that embodiments of the present invention will be described in terms of a given illustrative architecture; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The present invention may include a design for an integrated circuit chip, which may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be understood that the various layers and/or regions shown in the accompanying drawings are not drawn to scale, and that one or more layers and/or regions of a type commonly used in complementary metal-oxide semiconductor (CMOS), field-effect transistor (FET), fin field-effect transistor (finFET), metal-oxide-semiconductor field-effect transistor (MOSFET), and/or other semiconductor devices may not be explicitly shown in a given drawing. This does not imply that the layers and/or regions not explicitly shown are omitted from the actual devices. In addition, certain elements may be left out of particular views for the sake of clarity and/or simplicity when explanations are not necessarily focused on the omitted elements. Moreover, the same or similar reference numbers used throughout the drawings are used to denote the same or similar features, elements, or structures, and thus, a detailed explanation of the same or similar features, elements, or structures will not be repeated for each of the drawings.

Deposition may be any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others.

Removal may be any process that removes material from the wafer; examples include etch processes (either wet or dry) and chemical-mechanical planarization (CMP).

Patterning refers to the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed by plasma ashing.

The BEOL layer of a semiconductor integrated circuit typically comprises multiple levels of metal lines and inter-level metallic vias that connect various integrated circuit component and devices fabricated as part of the FEOL layer. As semiconductor devices and their features continue to be scaled down new technologies and processes are needed to fabricate these devices and features. With respect to BEOL interconnects, various issues may arise during their fabrication. For example, conventional fabrication processes typically deposit a dielectric layer; form the top-via interconnect structures within the dielectric layer; perform an etch back process to remove the dielectric layer; and then perform a dielectric gap fill process to form another dielectric layer over and between the interconnect structures. However, as the pitch between the interconnect structures becomes increasingly narrower (e.g., 24 nm or less) these conventional fabrication processes typically have problems removing all of the dielectric between the interconnect structures during the etch back process. The narrow pitch also makes it difficult to perform the subsequent dielectric gap fill process such that the dielectric material reaches the bottom of the gap between interconnect structures. Even further, the interconnect structures tend to collapse during the wet etch process, which is performed after the etch back process, due to the high aspect ratio (e.g., greater than 4:1) and the critical dimension (e.g., less than 14 nm) of the features.

As will be discussed in greater detail below, embodiments of the present invention overcome these and other problems by utilizing a dual dielectric layer configuration that does not require the dielectric etch back and gap fill processes. For example, in one embodiment, a first dielectric layer is formed on a cap layer. An insulating layer is then formed on the first dielectric layer. The oxide and first dielectric layers are patterned to form a plurality of interconnect trenches. Each interconnect trench is filed with an interconnect material to form a plurality of interconnect structures. Each interconnect structure is patterned into a top-via configuration comprising a metal layer/wire and a metal via pillar on top of the metal layer/wire. The insulating layer is subsequently removed while the first dielectric layer is maintained in contact with and between the metal layers/wires of the interconnect structures. A second dielectric layer, which may comprise the same or different material than the first dielectric layer, is then deposited over the structure and subsequently polished back. The second dielectric layer is formed on the top surface of the first dielectric layer, the top surface of the metal layers/wires, and the sidewalls of the metal via pillars. Because the first dielectric layer is maintained, the conventional dielectric etch process is not required and the second dielectric layer is not required to reach the bottom of the gap between the interconnect structures. In addition, collapsing of the interconnect structures is prevented since the aspect ratios are reduced and wet cleansing is utilized to only remove the second dielectric layer is removed, which reduces the chance of pattern collapse.

FIGS. 1-9 illustrate various processes for forming metallic interconnect structures according to one or more embodiments of the present invention. Referring now to FIG. 1, a semiconductor device structure 100 at an intermediate stage of fabrication is shown. In this example, the structure 100 may comprise a semiconductor substrate 102 (e.g., semiconductor wafer), a FEOL (front-end-of-line)/MOL (middle-of-line) structure 104 formed on the substrate 102, a capping layer 106, and a first dielectric layer 108.

It should be noted that while the semiconductor substrate 102 is illustrated as a generic substrate layer it is to be understood that the semiconductor substrate 102 may comprise one of various different types of semiconductor substrate structures and materials. For example, in one embodiment, the semiconductor substrate 102 may be a bulk semiconductor substrate (e.g., wafer) that is formed of silicon (Si) or germanium (Ge), or other types of semiconductor substrate materials that are commonly used in bulk semiconductor fabrication processes such as a silicon-germanium alloy, compound semiconductor materials (e.g. III-V), etc. In another embodiment, the semiconductor substrate 102 may be an active semiconductor layer of an SOI (silicon-on-insulator) substrate, GeOI (germanium-on-insulator) substrate, or other type of semiconductor-on-insulator substrate, which comprises an insulating layer (e.g., oxide layer) disposed between a base substrate layer (e.g., silicon substrate) and the active semiconductor layer (e.g., Si, Ge, etc.) in which active circuit components are formed as part of the FEOL. It is to be noted that in each drawing, the X-Y plane represents a plane that is parallel to the plane of the semiconductor substrate 102 (e.g., wafer) being processed.

The FEOL/MOL structure 104 may comprise an FEOL layer formed on the semiconductor substrate 102. The FEOL layer may comprise various semiconductor devices and components that are formed in or on the active surface of the semiconductor substrate 102 to provide integrated circuitry for a target application. For example, the FEOL layer may comprise field-effect transistor (FET) devices (such as FinFET devices, vertical FET devices, planar FET device, etc.), bipolar transistors, diodes, capacitors, inductors, resistors, isolation devices, etc., which are formed in or on the active surface of the semiconductor substrate 102. In general, FEOL processes may typically include preparing the semiconductor substrate 102 (or wafer), forming isolation structures (e.g., shallow trench isolation), forming device wells, patterning gate structures, forming spacers, forming source/drain regions (e.g., via implantation), forming silicide contacts on the source/drain regions, forming stress liners, etc.

The FEOL/MOL structure 104 may further comprise an MOL layer formed on the FEOL layer. In general, the MOL layer may comprise a PMD (pre-metal dielectric layer) and conductive contacts (e.g., via contacts) that are formed in the PMD layer. The PMD layer may be formed on the components and devices of the FEOL layer. A pattern of openings may be formed in the PMD layer and the openings may be filled with a conductive material, such as tungsten, to form conducive via contacts that are in electrical contact with device terminals (e.g., source/drain regions, gate contacts, etc.) of the integrated circuitry of the FEOL layer. The conductive via contacts of the MOL layer provide electrical connections between the integrated circuitry of the FEOL layer and a first level of metallization of a BEOL structure that is formed on the FEOL/MOL structure 104.

In the example shown in FIG. 1, the capping layer 106 and the first dielectric layer 108 may formed as part of an initial phase of a BEOL process module to form a first metallization level of a BEOL interconnect structure. The capping layer 106 may be a layer of insulating/dielectric material such as silicon nitride (SiN), silicon carbide (SiC), silicon carbon nitride (SiCN), hydrogenated silicon carbide (SiCH), or a multilayer stack comprising the same or different types of dielectric materials, etc., or other suitable low-k dielectric materials that are non-reactive with the metallic material that is used to form metallic interconnect structures in the BEOL.

The first dielectric layer 108 may be formed of any suitable dielectric material that is commonly utilized as an interlevel-dielectric (ILD) layer for BEOL process technologies. For example, the first dielectric layer 108 may be formed of a dielectric material including, but not limited to, silicon oxide (SiO2), silicon nitride (e.g., (Si3N4), hydrogenated silicon carbon oxide (SiCOH), SiCH, SiCNH, or other types of silicon-based low-k dielectrics (e.g., k less than about 4.0), porous dielectrics, or known ULK (ultra-low-k) dielectric materials (with k less than about 2.5). The thickness of the first dielectric layer 108 may define a vertical height (or thickness) of the metallization that is formed within the first dielectric layer 108, which will vary depending on the application. The capping layer 106 and the first dielectric layer 108 may be formed using known deposition techniques, such as, for example, ALD (atomic layer deposition), CVD (chemical vapor deposition) PECVD (plasma-enhanced CVD), or PVD (physical vapor deposition), spin-on deposition, and/or the like.

FIG. 2 shows that, in one embodiment, an insulating layer 202 is formed on and in contact with a top surface of the first dielectric layer 108. In one embodiment, the insulating layer 202 is derived from TEOS (tetraethylorthosilicate) and deposited using a TEOS-based deposition method. However, other oxides, silicon nitrides, and deposition methods are applicable as well. A patterning stack 204 may then be formed over and in contact with the insulating layer 202. The patterning stack 204 may comprise a photoresist layer, a tri-layer stack, quad-layer stack, or any other applicable patterning stack configuration. In the example shown in FIG. 2, a desired pattern has been transferred to each layer in the patterning stack 204 to form one or more openings 206, 208 therein. Each opening 206, 208 exposes a portion of the underlying insulating layer 202.

The defined pattern may then be transferred to the insulating layer 202 and underlying portions of the first dielectric layer 108 as shown in FIG. 3. For example, a dry etch process such as RIE (reactive ion etching), which has an etch chemistry that is suitable to etch the insulating layer 202 and the first dielectric layer 108 selective to the underlying capping layer 106, may be used to etch the exposed portions of the insulating layer 202 and underlying portions of the first dielectric layer 108. The etching process stops on the capping layer 106 and forms one or more interconnect trenches 302, 304 that extend through the insulating layer 202 and first dielectric layer 108. The patterning stack 204 may then be removed by, for example, reactive ion etches (RIE).

FIG. 4 shows that the interconnect trenches 302, 304 are filled with a first interconnect material 402. For example, a copper seed may be deposited within each interconnect trench 302, 304 via PVD followed by copper plating. However, CVD techniques may be used as well. It should be noted that other materials and processes may be utilized to form/deposit the first interconnect material 402. For example, copper, cobalt, tungsten, aluminum, ruthenium, a combination thereof, and other the like may be used to fill the trenches. It should be noted that, in some embodiments, a diffusion barrier layer (not shown) may be formed within the trenches 302, 304 prior to filling the trenches with the interconnect material 402. The diffusion barrier material may be formed using materials that are commonly used as diffusion barrier layers for metal interconnects including, but not limited to, titanium (Ti), tantalum (Ta), titanium nitride (TiN), tantalum nitride (TaN), etc. The diffusion barrier layer may be deposited using a deposition process such as PVD or any other applicable process.

Excess interconnect material 402 may then be removed by, for example, CMP as shown in FIG. 5. This process forms interconnect structures 502, 504 within each interconnect trench 302, 304. In one embodiment, the top surface of the interconnect structures 502, 504 are planar with the top surface of the insulating layer 202. FIG. 5 further shows a patterning stack 506 may be formed over the structure 100. The patterning stack 506 may comprise a photoresist layer, a tri-layer stack, quad-layer stack, or any other applicable patterning stack configuration. In the example shown in FIG. 5, a desired pattern has been defined within the patterning stack 506, where a first portion of the interconnect structures 502, 504 is covered while openings 508, 510 expose a second portion of the interconnect structures 502, 504.

FIG. 6 shows that, in one embodiment, a metal etching process is performed to remove the exposed portions of the interconnect structures 502, 504. In one embodiment, the exposed portions of the interconnect structures 502, 504 are etched down to the first dielectric layer 108. The patterning stack 506 may then be removed by, for example, RIE. The metal etching process results in the interconnect structures 502, 504 having a top via configuration. For example, FIG. 6 shows the interconnect structures 502, 504 comprising metal filled trenches 602, 604 (also referred to herein as “metallic layers/wires 602, 604”) in the lower regions of the interconnect structures 502, 504 and metallic via pillars 606, 608 in the upper regions of the interconnect structures 502, 504. In one embodiment, the via pillars 606, 608 are 12 to 18 nm wide although other dimensions are applicable as well.

The insulating layer 202 may then be removed as shown in FIG. 7. In one embodiment, the insulating layer 202 is removed using, for example, RIE, wet etch, or a combination of RIE an wet etch. FIG. 7 further shows that the first dielectric layer 108 is maintained and not etched away unlike most conventional fabrication processes for forming top-via interconnect structures. The portion of the first dielectric layer 108 between the interconnect structures 502, 504 helps prevent collapsing of the metallic via pillars 606, 608 due to a lower aspect ratio as compared to removing both the first dielectric layer 108 and the insulating layer 202.

After the insulating layer 202 has been removed, a second dielectric layer 802 may be formed over the structure 100 and subsequently polished down as shown in FIG. 8. The second dielectric layer 802 may be polished down using, for example, CMP, such that a top surface of the second dielectric layer 802 is planar with a top surface of the metallic via pillars 606, 608 or the adhesion layer 702 if formed. In one embodiment, the second dielectric layer 802 is disposed adjacent to and between the metallic via pillars 606, 608 of the interconnect structures 502, 504 and may be formed on the top surface of the first dielectric layer 108; the portion of the adhesion layer 702 formed on the metallic layers/wires 602, 604; and portions of the adhesion layer 702 formed on sidewalls of the metallic via pillars 606, 608. In an embodiment where the adhesion layer 702 is not been formed, the second dielectric layer 802 is formed on the top surface of the first dielectric layer 108; the top surface of the metallic layers/wires 602, 604; and sidewalls of the metallic via pillars 606, 608. Although not shown, an optional CMP stop layer may be formed on the top surface of the metallic via pillars 606, 608.

The second dielectric layer 802 may comprise the same or different material than the first dielectric layer 108. For example, the second dielectric layer 802 may be formed of any suitable dielectric material that is commonly utilized as an ILD layer for BEOL process such as a dielectric material including, but not limited to, SiO2, Si3N4, SiCOH, SiCH, SiCNH, or other types of silicon-based low-k dielectrics (e.g., k less than about 4.0), porous dielectrics, or known ULK dielectric materials (with k less than about 2.5). The second dielectric layer 802 may be formed using known deposition techniques, such as, for example, CVD, PECVD, PVD, or spin-on deposition, and/or the like. Subsequent processing may then be performed to form one or more layers above the formed interconnect structures 502, 504.

FIGS. 9-15 illustrate various processes for forming metallic interconnect structures according to another embodiment of the present invention. FIG. 9 shows a semiconductor structure 900 at an intermediate stage of fabrication comprising a semiconductor substrate 902 (e.g., semiconductor wafer); a FEOL (front-end-of-line)/MOL (middle-of-line) structure 904 formed on the substrate 902; a capping layer 906; a first dielectric layer 908; one or more interconnect structure material 910, 912; an insulating layer 914; and a patterning stack 916. These features are similar to the features discussed above with respect to FIG. 1-5. However, instead of defining a pattern for forming the metallic via pillars 606, 608 of FIG. 6 the patterning stack 916 shown in FIG. 9 comprises a pattern for etching the full length and width of the interconnect structure material 910, 912 down to the first dielectric layer 908. For example, FIG. 9 shows that the patterning stack 916 comprises openings 918, 920 exposing the entire top surface of the interconnect structure material 910, 912.

FIG. 10 shows that a metal etching process may be performed to etch the interconnect structures material 910, 912 down to at least the first dielectric layer 908 to form metallic layers/wires 1002, 1004 for the interconnect structures similar to the metallic layers/wires 602, 604 discussed above with respect to FIG. 6. The etching process also forms a trench 1006, 1008 above each metallic layer/wire 1002, 1004. After the metallic layers/wires 1002, 1004 have been formed, the patterning stack 916 may be removed by, for example, RIE. The trenches 1006, 1008 may then be filled with a second interconnect material 1102 as shown in FIG. 11.

In one embodiment, the second interconnect material 1102 comprises copper, cobalt, tungsten, aluminum, ruthenium, a combination thereof, and other the like. In one embodiment, the second interconnect material 1102 is different than the first interconnect material used to form the metallic layers/wires 1002, 1004. For example, the metallic layers/wires 1002, 1004 may comprise copper while the second interconnect material 1102 may comprise ruthenium. The second interconnect material 1102 may be deposited using, for example, PVD, CVD, electroplating, or combinations of these deposition processes.

FIG. 12 shows that the second interconnect material 1102 may be polished down to the top surface of the insulating layer 914 using, for example, CMP to form separate layers 1202, 1204 of second interconnect material 1102 within each trench 1006, 1008. FIG. 12 further shows that another patterning stack 1206 may be formed over the structure 100. The patterning stack 1206 of FIG. 12 is similar to the patterning stack 506 of FIG. 5 and comprises a similar pattern to define via pillars within each second interconnect material layer 1202, 1204. For example, the patterning stack 1206 covers a first portion of each second interconnect material layer 1202, 1204 while openings 1208, 1210 expose a second portion of second interconnect material layer 1202, 1204.

A metal etching process may then be performed to remove the exposed portions of each second interconnect material layer 1202, 1204 as shown in FIG. 13. In one embodiment, the exposed portions of the second interconnect material layer 1202, 1204 are etched down to the metallic layers/wires 1002, 1004 thereby forming metal/metallic via pillars 1302, 1304. The patterning process results in hybrid metallized interconnect structures 1306, 1308 having a top via configuration where the metallic layers/wires 1002, 1004 and metallic via pillars 1302, 1304 are comprised of different materials. This is in contrast to the top via configuration of the embodiment shown in FIG. 6 where the metallic layers/wires 602, 604 and metallic via pillars 608, 608 are comprised of the same materials.

After the metallic via pillars 1302, 1304 have been formed, similar processing to that discussed above with respect to FIGS. 7 and 8 may be performed. For example, FIG. 14 shows that the patterning stack 916 and insulating layer 914 may be removed using, for example, RIE or any other suitable process. In some embodiments, a portion of the first dielectric layer 908 may also be etched away in addition to the insulating layer 914. FIG. 14 further shows that an optional interface/adhesion layer 1402 is deposited on the top surface of the structure 900 similar to the interface/adhesion layer 702 of FIG. 7. The optional interface/adhesion layer 1402 may be formed on and in contact with a top surface of the first dielectric layer 108; a top surface of the metallic layers/wires 1002, 1004; sidewalls of the metallic via pillars 1302, 1304; and a top surface of the metallic via pillars 1302, 1304.

A second dielectric layer 1502 may then be formed over the structure 900 and subsequently polished down as shown in FIG. 15. The second dielectric layer 1502 may be polished down using, for example, CMP, such that a top surface of the second dielectric layer 1502 is planar with a top surface of the metallic via pillars 1302, 1304. In one embodiment, the second dielectric layer 1502 is disposed adjacent to and between the metallic via pillars 1302, 1304 and may be formed on the top surface of the first dielectric layer 908; the portion of the adhesion layer 1402 formed on the metallic layers/wires 1002, 1004; and portions of the adhesion layer 1402 formed on sidewalls of the metallic via pillars 1302, 1304. In an embodiment where the adhesion layer 1402 is not been formed, the second dielectric layer 1502 is formed on the top surface of the first dielectric layer 908; the top surface of the metallic layers/wires 1002, 1004; and sidewalls of the metallic via pillars 1302, 1304. Although not shown, an optional CMP stop layer may be formed on the top surface of the metallic via pillars 1302, 1304.

The second dielectric layer 1502 may comprise the same or different material than the first dielectric layer 908. For example, the second dielectric layer 1502 may be formed of any suitable dielectric material that is commonly utilized as an ILD layer for BEOL process such as a dielectric material including, but not limited to, SiO2, Si3N4, SiCOH, SiCH, SiCNH, or other types of silicon-based low-k dielectrics (e.g., k less than about 4.0), porous dielectrics, or known ULK dielectric materials (with k less than about 2.5). The second dielectric layer 1502 may be formed using known deposition techniques, such as, for example, ALD, CVD, PECVD, PVD, or spin-on deposition, and/or the like. Subsequent processing may then be performed to form one or more layers above the formed interconnect structures 1306, 1308.

FIG. 16 is an operational flow diagram illustrating one example of a process for forming interconnect structure having a top-via configuration. It should be noted that each of the steps shown in FIG. 16 has been discussed in greater detail above with respect to FIGS. 1 to 8. Beginning at step 1602, a first dielectric layer is formed on a substrate. An insulating layer is formed on the first dielectric layer at step 1604. At least one trench is formed that extends through the insulating layer and the first dielectric layer at step 1606. An interconnect material is deposited and fills the at least one trench at step 1608. The interconnect material is patterned into an interconnect structure comprising a top-via configuration at step 1610. The insulating layer is removed after the interconnect material has been patterned at step 1612. A second dielectric layer is formed on the first dielectric layer and the patterned interconnect structure at step 1614.

FIG. 17 is an operational flow diagram illustrating one example of a process for forming interconnect structure having a top-via configuration. It should be noted that each of the steps shown in FIG. 17 has been discussed in greater detail above with respect to FIGS. 8 to 15. Beginning at step 1702, a first dielectric layer is formed on a substrate. An insulating layer is formed on the first dielectric layer at step 1704. At least one trench is formed that extends through the insulating layer and the first dielectric layer at step 1706. A first interconnect material is deposited and fills the at least one trench at step 1708. The first interconnect material is etched down into the at least one trench to form a wire layer of an interconnect structure at step 1710. A second interconnect structure is deposited into the at least one trench in contact with the metal wire at step 1712. The second interconnect material is patterned to form a via pillar of the interconnect structure at step 1714.

Although specific embodiments of the invention have been taught, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

It should be noted that some features of the present invention may be used in one embodiment thereof without use of other features of the present invention. As such, the foregoing description should be considered as merely illustrative of the principles, teachings, examples, and exemplary embodiments of the present invention, and not a limitation thereof.

Also, these embodiments are only examples of the many advantageous uses of the innovative teachings herein. In general, statements made in the specification of the present application do not necessarily limit any of the various claimed embodiments. Moreover, some statements may apply to some inventive features but not to others.

What is claimed is:

1. A method, comprising:
forming a first dielectric layer on a substrate;
forming an insulating layer on the first dielectric layer;
forming at least one trench extending through the insulating layer and the first dielectric layer;
depositing an interconnect material to fill the at least one trench;
patterning the interconnect material into an interconnect structure comprising a top-via configuration;
removing the insulating layer while maintaining the first dielectric layer; and
forming a second dielectric layer on the first dielectric layer and the patterned interconnect structure.

2. The method of claim 1, wherein patterning the interconnect material into the top-via configuration comprises:
forming a patterning stack over the insulating layer and a portion of the interconnect material; and
partially etching exposed portions of the interconnect material to form a wire layer in a lower region of the interconnect structure and a via pillar on top of and in contact with the wire layer in an upper region of the interconnect structure.

3. The method of claim 2, wherein partially etching the exposed portions of the interconnect material comprises:
etching the exposed portions of the interconnect material down to a top surface of the first dielectric layer.

4. The method of claim 2, wherein forming the second dielectric layer comprises:
forming the second dielectric layer on the wire layer and the via pillar.

5. The method of claim 1, wherein the first dielectric layer and the second dielectric layer comprise different materials.

6. The method of claim 1, wherein the first dielectric layer and the second dielectric layer comprise identical materials.

7. The method of claim 1, further comprising:
forming a diffusion barrier layer within the at least one trench prior to depositing the interconnect material.

8. A method, comprising:
forming a dielectric layer over a substrate;
forming an insulating layer on the dielectric layer;
forming at least one trench extending through the insulating layer and the dielectric layer;
depositing a first interconnect material to fill the at least one trench;
etching the first interconnect material down into the at least one trench to form a wire layer of an interconnect structure;
depositing a second interconnect material into the at least one trench and in contact with the wire layer; and
patterning the second interconnect material to form a via pillar of the interconnect structure.

9. The method of claim 8, wherein the first interconnect material is different than the second interconnect material.

10. The method of claim 8, further comprising:
removing the insulating layer; and
forming an additional dielectric layer on the dielectric layer, the wire layer of the interconnect structure, and the via pillar of the interconnect structure.

11. The method of claim 8, wherein etching the first interconnect material comprises:
etching the first interconnect material down to a top surface of the dielectric layer.

12. The method of claim 8, wherein patterning the second interconnect material comprises:
forming a pattern over a portion of the second interconnect material thereby exposing a remaining portion of the second interconnect material; and
etching the remaining portion of the second interconnect material.

13. The method of claim 12, wherein etching the remaining portion of the second interconnect material comprises:
etching the remaining portion of the second interconnect material down to a top surface of the wire layer.

14. A semiconductor structure comprising:
a first dielectric layer disposed over a substrate;
a second dielectric layer disposed over and in contact with the first dielectric layer, wherein the first dielectric layer comprises a different low-k dielectric material than the second dielectric layer; and
at least one interconnect disposed within the first dielectric layer and the second dielectric layer,
wherein the at least one interconnect comprises a top-via configuration.

15. The semiconductor structure of claim 14, wherein the top-via configuration of the at least one interconnect comprises:
a metallic wire layer; and
a metallic via pillar disposed on top of and in contact with a top surface of the metallic wire layer.

16. The semiconductor structure of claim 15, wherein sidewalls of the metallic wire layer are in contact with the first dielectric layer, and wherein a top surface of the metallic wire layer and sidewalls of the metallic via pillar are in contact with the second dielectric layer.

17. The semiconductor structure of claim 15, wherein the metallic wire layer comprises a different material than the metallic via pillar.

18. The semiconductor structure of claim 15, wherein the metallic wire layer comprises a same material as the metallic via pillar.

19. The semiconductor structure of claim 14, further comprising:
an adhesion layer disposed in contact with the at least one interconnect.

20. The semiconductor structure of claim 14, wherein a top surface of the first dielectric layer is planar with a top surface of the metallic wire layer.
